(19) United States
(12) Patent Application Publication
(10) Pub. No.: US 2025/0216727 A1
(43) Pub. Date: Jul. 3, 2025

(54) DISPLAY PANEL AND DISPLAY APPARATUS INCLUDING THE SAME

(71) Applicant: LG Display Co., Ltd., Seoul (KR)

(72) Inventor: Nam Kil PARK, Paju-si (KR)

(21) Appl. No.: 18/935,055

(22) Filed: Nov. 1, 2024

(30) Foreign Application Priority Data
Dec. 29, 2023 (KR) 10-2023-0197393

(51) Int. Cl. G02F 1/1345; G06F 3/044

(52) U.S. Cl. CPC G02F 1/13452; G06F 3/0443

(57) ABSTRACT

One embodiment of the present disclosure discloses a display panel including a substrate having a display area and a non-display area in the periphery of the display area, a plurality of signal wires extending from the display area to the non-display area, a plurality of driving pads that is disposed in a first area, to which a driver IC is attached in the non-display area and the is connected to the plurality of signal wires, and a dummy pad disposed in the first area, wherein a positive voltage is applied to the dummy pad, and a display apparatus including the same.

### CROSS-REFERENCE TO RELATED APPLICATION

This application claims priority to and the benefit of Korean Patent Application No. 10-2023-0197393, filed Dec. 29, 2023, the disclosure of which is incorporated herein by reference in its entirety.

### BACKGROUND

### Technical Field

The present disclosure relates to a display panel and a display apparatus including the same.

### Description of the Related Art

In the recent information society, display apparatuses are becoming more important as a visual information delivery medium, and in order to occupy a major position in the future, they must meet the requirements of low power consumption, thinness, light weight, and high definition.

A display apparatus may be divided into a light emission type, such as Electro Luminescence EL, Light-Emitting Diode (LED), and Field Emission Display (FED), which emit light itself, and a non-light-emitting type, such as Liquid Crystal Display (LCD), which do not emit light itself.

### BRIEF SUMMARY

The display apparatus may be electrically connected to a driver integrated circuit (driver IC) by extending signal wires from a display area to a non-display area. The inventors of the present disclosure have recognized that in this case, the signal wires and pads are subject to corrosion from external moisture introduced by a high temperature, high humidity operating environment. Such badness often occurs in the pad located at the edge of the driver IC, resulting in poor driving. Various embodiments of the present disclosure have been provided to address one or more problems in the related art, including the aforementioned technical issue.

An embodiment of the present disclosure provides a display panel that may prevent corrosion of a driving pad by negative charges and a display apparatus including the display panel.

The problem to be solved by the embodiment is not limited to the problem mentioned above, and other problems not mentioned herein will be clearly understood by those skilled in the art from the following description.

A display panel according to an embodiment of the present disclosure, includes: a substrate having a display area and a non-display area in the periphery of the display area, a plurality of signal wires extending from the display area to the non-display area, a plurality of driver pads disposed in a first area where a driver IC is disposed in the non-display area and connected to the plurality of signal wires, and a dummy pad disposed in the first area. A positive voltage is applied to the dummy pad.

A display apparatus according to an embodiment of the present disclosure includes: a substrate having a display area and a non-display area in the periphery of the display area, a plurality of signal wires extending from the display area to the non-display area, a plurality of driving pads disposed in a first area of the non-display area and connected to the plurality of signal wires, a dummy pad disposed in the first area, and a driver IC disposed in the first area. A plurality of dummy pads includes a plurality of dummy signal wires extending toward the display area.

According to one or more embodiments of the present disclosure, it is possible to prevent or delay the driving pads from reacting with negative charges present in the area where the driver IC is mounted, thereby improving the bad driving pads. This may enable low-voltage driving and improve the reliability of the display apparatus.

The effects of the present disclosure are not limited to the effects mentioned above, and other effects not mentioned will be apparent to one having ordinary skill in the art to which the technical ideas of the present disclosure belong from the following description.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a plan view illustrating a display apparatus according to an embodiment of the present disclosure;

FIG. 2 is a diagram illustrating a signal wire and a driving pad in a display apparatus according to an embodiment of the present disclosure;

FIG. 3 is a cross-sectional view illustrating a display apparatus which is bent according to an embodiment of the present disclosure;

FIGS. 4 and 5 are circuit diagrams illustrating various pixel circuits of a display apparatus according to an embodiment of the present disclosure;

FIG. 6 is a waveform diagram illustrating a driving signal applied to the pixel circuit shown in FIG. 5;

FIG. 7 is a cross-sectional view illustrating a cross-sectional structure of a display area according to an embodiment of the present disclosure;

FIG. 8 is a cross-sectional view illustrating a cross-sectional structure of a display area according to another embodiment of the present disclosure;

FIG. 9 is a diagram illustrating of a cross-sectional structure of a display area according to another embodiment of the present disclosure;

FIG. 10 is a diagram illustrating a signal wire and a pad in a display apparatus according to another embodiment of the present disclosure;

FIG. 11 is a diagram illustrating an area EA of FIG. 10;

FIG. 12 is a cross-sectional view of a driving pad and a dummy pad according to an embodiment of the present disclosure;

FIG. 13 is a diagram illustrating a potential level of the area EA of FIG. 10;

FIG. 14 is a diagram illustrating that negative charges are concentrated at an edge of a first area in which a driver IC is disposed;

FIGS. 15A to 15D are diagrams illustrating that electrolytic corrosion in a driving pad occurs due to negative charges charged on an edge;

FIG. 16 is a plot where the number of times a defect has occurred in each driving pad is measured;

FIGS. 17 to 19 are diagrams illustrating various connection relationships of a dummy pad in a display apparatus according to an embodiment of the present disclosure;

FIG. 20 is a diagram illustrating an operation timing of a pixel circuit in a display apparatus according to an embodiment of the present disclosure;

FIG. 21 is a block diagram of a driver IC according to an embodiment of the present disclosure;

FIG. 22 is a diagram illustrating that a plurality of dummy pads are electrically connected using a gate wire in a display apparatus according to an embodiment of the present disclosure;

FIG. 23 is a diagram illustrating that a dummy pad is electrically connected using a sensor electrode wire in a display apparatus according to an embodiment of the present disclosure;

FIG. 24 is a diagram illustrating that adjacent dummy pads are electrically connected using a data wire in a display apparatus according to an embodiment of the present disclosure;

FIG. 25 is a diagram illustrating that negative charges are immobilized by connecting a gate electrode in a display apparatus according to an embodiment of the present disclosure; and

FIG. 26 is a diagram illustrating a display apparatus according to another embodiment of the present disclosure.

### DETAILED DESCRIPTION

The advantages and features of the present disclosure, and methods of achieving them will be apparent from the embodiments described in detail below in conjunction with the accompanying drawings. However, the present disclosure is not limited to the following embodiments disclosed herein, but may be implemented in various different forms; rather, the present embodiments are provided to make the present disclosure complete and to enable those skilled in the art to fully comprehend the scope of the present disclosure.

The shapes, sizes, dimensions (e.g., length, width, height, thickness, radius, diameter, area, etc.), proportions, angles, numbers, and the like of elements shown in the drawings to illustrate embodiments of the present disclosure are merely illustrative and are not intended to be limiting.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Identical reference numerals may designate identical components throughout the description. Further, in describing the present disclosure, detailed descriptions of related known technologies may be omitted so as not to obscure the essence of the present disclosure. Terms such as “comprising,” “including,” “having,” or “consisting of” as used herein are generally intended to allow for the addition of other components, unless the terms are used with the term “only.” References to components of a singular noun include the plural of that noun, unless specifically stated otherwise.

In the interpretation of components, they are construed to include margins of error, even if this is not explicitly stated.

When describing a positional relationship, for example, “on top of,” “above,” “below,” or “next to” describes the positional relationship of two parts, one or more other parts may be located between the two parts, unless “immediately” or “directly” is used.

When describing a temporal relationship, “after,” “following,” “next to,” or “before” describes a temporal antecedent or consequent relationship, which may not be continuous unless “immediately” or “directly” is used.

The first, the second, and so on are used to describe various components, but these components are not limited by these terms. These terms are used only to distinguish one component from another. Therefore, the first component referred to below may be a second component within the technical spirit of the present disclosure.

Terms such as first, second, A, B, (a), or (b) may be used to describe elements of the embodiments of the present disclosure. Such terms are intended only to distinguish one component from another and are not intended to define the nature, sequence, order, or number of such components. When a component is described as being “connected,” “coupled,” or “attached” to another component, it is to be understood that the component may be directly connected or attached to the other component, but that there may also be other components “interposed” between the respective components which may be indirectly connected or attached unless not specifically stated.

It should be understood that the term “at least one” includes all possible combinations of one or more related components. For example, the meaning of “at least one of the first, second, and third components” can be understood to include not only the first, second, or third component, but also any combination of two or more of the first, second, and third components.

According to one or more embodiments of the present disclosure, when a display panel is a liquid crystal display panel, it may include a plurality of gate lines and data lines, and pixels formed at intersections between the gate lines and the data lines. In addition, it may include a first substrate including a thin film transistor as a switching element for controlling light transmittance in each pixel, a second substrate including a color filter and/or a black matrix, and a liquid crystal layer between the first and second substrates.

When the display panel is an organic light-emitting display panel, it may include a plurality of gate lines and data lines, and pixels formed at intersections between the gate lines and the data lines. In addition, it may include a substrate including a thin-film transistor as an element for selectively applying a voltage to each pixel, an organic emissive element layer on the substrate, and an encapsulation layer (or encapsulation substrate) disposed on the substrate to cover the organic emissive element layer. The encapsulation substrate may protect the thin-film transistor and the organic emissive element layer from external impacts and prevent the ingress of moisture or oxygen into the organic emissive element layer. The organic emissive element layer may further include an inorganic light-emitting layer (e.g., a nano-sized material layer), and/or a quantum dot light-emitting layer. In another example, the organic emissive element layer may be changed to a micro light-emitting diode.

The pixel circuit and the gate driver formed on the display panel of the present disclosure may include a plurality of transistors. The transistors may be implemented as an oxide TFT (thin film transistor) including an oxide semiconductor, an LTPS TFT including a low temperature poly silicon (LTPS), and the like. Each of the transistors may be implemented as a p-channel TFT or an n-channel TFT.

A transistor is a three-electrode element including a gate, a source, and a drain. Here, the source is an electrode that supplies carriers to the transistor. And in the transistor, the carriers start to flow from the source. In addition, the drain is an electrode through which the carriers exit from the transistor. And in the transistor, the carriers flow from the source to the drain. In the case of an n-channel transistor (NMOS transistor), since the carriers are electrons, a source voltage is lower than a drain voltage, allowing the electrons to flow from the source to the drain. In this case, in the n-channel transistor, the direction of the current is from the drain to the source. In the case of a p-channel transistor (PMOS transistor), since the carriers are holes, a source voltage is higher than a drain voltage, allowing the holes to flow from the source to the drain. And in the p-channel transistor, the current flows from the source to the drain because the holes flow from the source to the drain. It should be noted that the source and the drain of the transistor are not fixed. For example, the source and the drain may be changed according to an applied voltage. Therefore, the present disclosure is not limited by the source and the drain of the transistor. In the following description, the source and the drain of a transistor will be referred to as a first electrode and a second electrode.

A gate signal may swing between a gate-on voltage and a gate-off voltage. The gate-on voltage may be set to a voltage higher than the threshold voltage of the transistor, and the gate-off voltage may be set to a voltage lower than the threshold voltage of the transistor. The transistor may be turned on in response to the gate-on voltage, whereas it may be turned off in response to the gate-off voltage. In the case of the n-channel transistor, the gate-on voltage may be a gate high voltage VGH/VEH, and the gate-off voltage may be a gate low voltage VGL/VEL. In case of the p-channel transistor, the gate-on voltage may be a gate low voltage VGL/VEL, and the gate-off voltage may be a gate high voltage VGH/VEH.

Each of the features of various embodiments described herein may be coupled or combined with one another in whole or in part, and may be technologically interlocked and operated in various ways, and each of the embodiments may be carried out independently or in conjunction with one another.

Hereinafter, embodiments of the present disclosure are illustrated by way of the accompanying drawings and examples. The dimensions of the components shown in the drawings are to scale for illustrative purposes only and are not to scale with the actual components shown in the drawings.

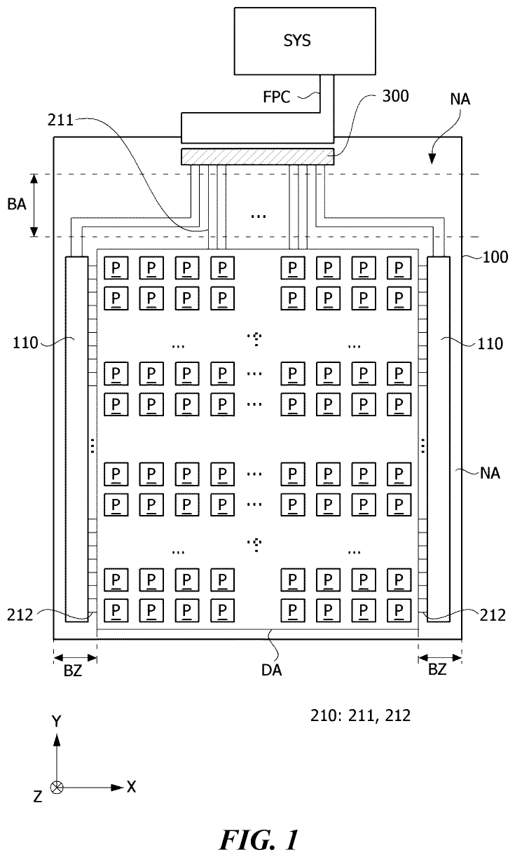

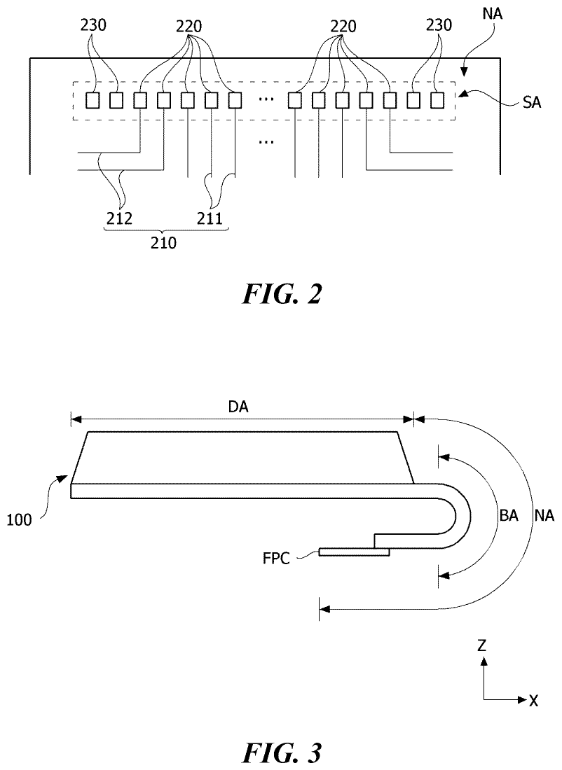

FIG. 1 is a plan view illustrating a display apparatus according to an embodiment of the present disclosure. FIG. 2 is a diagram illustrating a signal wire and a driving pad in the display apparatus according to an embodiment of the present disclosure. FIG. 3 is a cross-sectional view illustrating a display apparatus which is bent according to an embodiment of the present disclosure.

Referring to FIGS. 1 and 2, the display apparatus according to an embodiment of the present disclosure may include a display panel 100, a plurality of signal wires 210, a plurality of driving pads 220, and a dummy pad 230.

The display panel 100 may include a display area DA and a non-display area NA. The non-display area NA may be in the periphery of the display area DA. For example, the non-visible area NA may be adjacent to the display area DA.

The plurality of signal wires 210 may extend from the display area DA to the non-display area NA. The plurality of signal wires 210 may include a plurality of data wire 211 and a plurality of gate wires 212.

The plurality of data wires 211, the plurality of gate wires 212, and a plurality of pixels P may be disposed in the display area DA of the display panel 100. For example, the plurality of gate wires 212 may be disposed intersecting with the plurality of data wires 211. The plurality of pixels P may be disposed in an area defined by the plurality of data wires 211 and/or the plurality of gate wires 212. For example, the plurality of pixels P may be arranged in a matrix form, but embodiments of the present disclosure are not limited thereto. In addition, the display panel 100 may include a bezel area BZ and a bending area BA which are located on the non-display areas NA outside the display area DA.

Each of the pixels P may include sub-pixels of different colors. The sub-pixels may include a red sub-pixel, a green sub-pixel, and a blue sub-pixel. Each of the pixels P may further include a white sub-pixel. In the following, the pixel may be interpreted as a sub-pixel unless otherwise defined. Further, each of the sub-pixels may include a pixel circuit.

The pixel circuit may include a light-emitting element, a driving element that supplies a current to the light-emitting element, one or more switch elements that switch current paths of the driving element and the light-emitting element, and a capacitor that maintains a voltage Vgs between a gate and a source of the driving element.

The light-emitting element may be implemented as an organic light-emitting diode (OLED). The OLED includes an organic compound layer formed between an anode and a cathode. The organic compound layer may include a hole injection layer (HIL), a hole transport layer (HTL), an electron blocking layer (EBL), an emission layer (EML), an electron transport layer (ETL), a hole blocking layer (HBL), and an electron injection layer (EIL), but is not limited thereto. Alternatively, the organic compound layer may further include a charge generation layer (CGL), such as a P-type charge generation layer and an N-type charge generation layer. When a voltage is applied to an anode electrode and a cathode electrode of the OLED, holes passing through the hole transport layer (HTL) and electrons passing through the electron transport layer (ETL) are moved to the emission layer (EML) to form excitons, resulting in the emission of visible light from the emission layer (EML).

The display panel driver may write the pixel data of the input image to the pixels P. The display panel driver may include a data driver and a gate driver 110. The data driver may supply a data voltage of the pixel data to the data wire 211. The gate driver 110 may sequentially supply a gate pulse to the gate wire 212. The data driver may be integrated into the driver IC 300. The driver IC 300 may be attached to the display panel 100.

The driver IC 300 may be connected to the data wire 211 through data output channels to supply a voltage of a data signal to the display area DA. The driver IC 300 may include a timing controller. The timing controller may transmit the pixel data of the input image received from a host system to the data driver, and control the operation timing of the data driver and the gate driver 110.

The data driver of the drive IC 300 may convert the pixel data into a gamma compensation voltage through a digital to analog converter (DAC) and output the data voltage.

The gate driver 110 may include a shift register together with a pixel array formed in a circuit layer of the display panel 100. The shift register of the gate driver 110 may sequentially supply a gate signal to the gate wire 212 under the control of the timing controller. The gate signal may include a scan pulse and an emission control pulse. The shift register may include a scan driver that outputs the scan pulse and an EM driver that outputs an EM pulse.

The host system SYS may be implemented by an application processor (hereinafter referred to as AP). The host system SYS may transmit the pixel data of the input image to the driver IC 300. The host system SYS may be connected to the driver IC 300 through a flexible printed circuit, such as an FPC (flexible printed circuit), but embodiments of the present disclosure are not limited thereto.

The driver IC 300 is illustrated as being disposed on the display panel 100, but is not necessarily limited thereto. For example, the driver IC 300 mounted on a flexible printed circuit board may be electrically connected to the display panel 100. The flexible circuit board may also be bonded to the display panel 100 by a bonding process in a state in which an anisotropic conductive film (ACF) is aligned in an area where the flexible circuit board FCB is to be bonded on the display panel 100.

In the display panel 100, a portion of the area including the driver IC 300 may be bent toward the back of the display panel 100 by means of a bending area BA. For example, for a smaller device, bending may be necessary for size reduction. However, it is not necessarily limited to that.

According to an embodiment of the present disclosure, the driver IC 300 may have a chip on panel (COP) structure disposed on the display panel 300. In the COP structure, a plurality of driving pads 220 may be disposed in the non-displayed area NA. The plurality of driving pads 220 may be disposed at ends (or one sides) of a plurality of signal wires 210 for connecting to the driver IC 300. The plurality of driving pads 220 may be disposed in a first area SA where the driver IC 300 is disposed.

According to an embodiment of the present disclosure, a dummy pad 230 disposed adjacent to the plurality of driving pads 220 may be further included.

A plurality of dummy pads 230 may be disposed in the first area SA to which the driver IC 300 is attached. The driving pads 220 are susceptible to electrolytic corrosion due to hydroxyl groups (OH—) caused by moisture introduced from the outside in a high temperature, high humidity environment. For example, during driving, the intensity of hydroxyl groups (OH—) in the floating region of the driver IC 300 may increase to introduce negative charges into an adjacent driving pad 220 supplied with a positive voltage, resulting in electrolytic corrosion of the driving pad 220.

The dummy pad 230 may prevent or inhibit the negative charges from reacting with the driving pad 220 by attracting the negative charges. For example, the dummy pad 230 may prevent the driving pad 220 supplied with the positive voltage from reacting with the negative charges caused by the introduction of external moisture. As a result, the electrolytic corrosion in the driving pad 220 may be prevented.

The electrolytic corrosion may be a phenomenon in which a current flows in a conductor and corrodes the conductor. Corrosion occurs regardless of whether a current is applied or not, while electrolytic corrosion occurs when a current flows through a conductor, such as a wire, causing the conductor to corrode through a redox reaction.

The dummy pad 230 may be disposed in the first area SA. The dummy pad 230 may be disposed at an edge of the first area SA. The edge or the floating area of the driver IC 300 may be an area where the intensity of the hydroxyl groups OH-increases during driving, resulting in a large introduction of the negative charges to an adjacent driving pad 220 supplied with a positive voltage. Therefore, the dummy pad 230 may be disposed in an edge of the driver IC 300.

The dummy pad 230 may be provided to match the number of bumps on the driver IC 300 in the number of pads. The number of bumps on the driver IC 300 may be provided in any suitable number to allow connection to a variety of the display panels. Thus, when some of the driving pads are unnecessary in a given panel, they may be formed into dummy pads 230. For example, the number of wires required may vary depending on the type of display panel or driver IC 300, and thus, the number of dummy pads 230 may also vary, but embodiments of the present disclosure are not limited thereto.

According to an embodiment of the present disclosure, a positive voltage may be applied to the dummy pad 230 to attract the negative charges accumulated at both edges of the first area SA, thereby preventing the negative charges from moving to the central portion where the driving pad 220 is disposed. This may prevent or delay the positive voltage applied to the driving pad from reacting with the negative charges and causing electrolytic corrosion.

Due to a process deviation and a device characteristic deviation caused by the manufacturing process of the display panel 100, there may be a difference in the electrical characteristic of the driving element for each sub-pixel, and such difference may increase as the driving time of the pixels elapses. In order to compensate for the deviation in the electrical characteristic of the driving element for each pixel, an internal compensation technique or an external compensation technique may be applied to an organic light emitting display device.

The internal compensation technique may sense a threshold voltage of the driving element for each sub-pixel by using an internal compensation circuit implemented in each pixel circuit and compensate the gate-source voltage Vgs of the driving element by the threshold voltage.

The external compensation technique may sense in real time a current or voltage of the driving element that varies according to the electrical characteristics of the driving elements by using an external compensation circuit. The external compensation technique may compensate for the deviation (or difference) of the electrical characteristics of the driving element in each pixel in real time by modulating the pixel data (or digital data) of the input image by the electrical characteristic deviation (or difference) of the driving element sensed for each pixel.

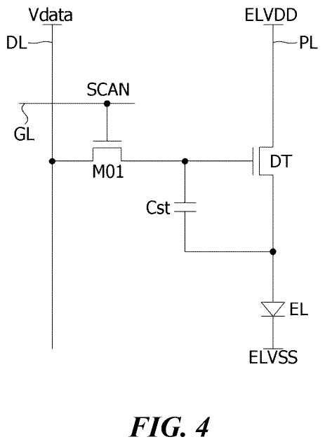

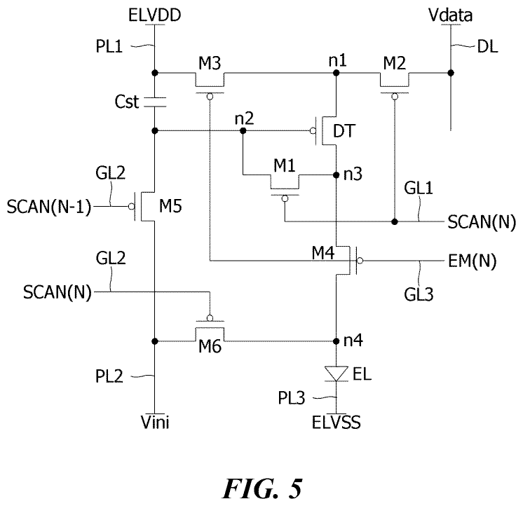

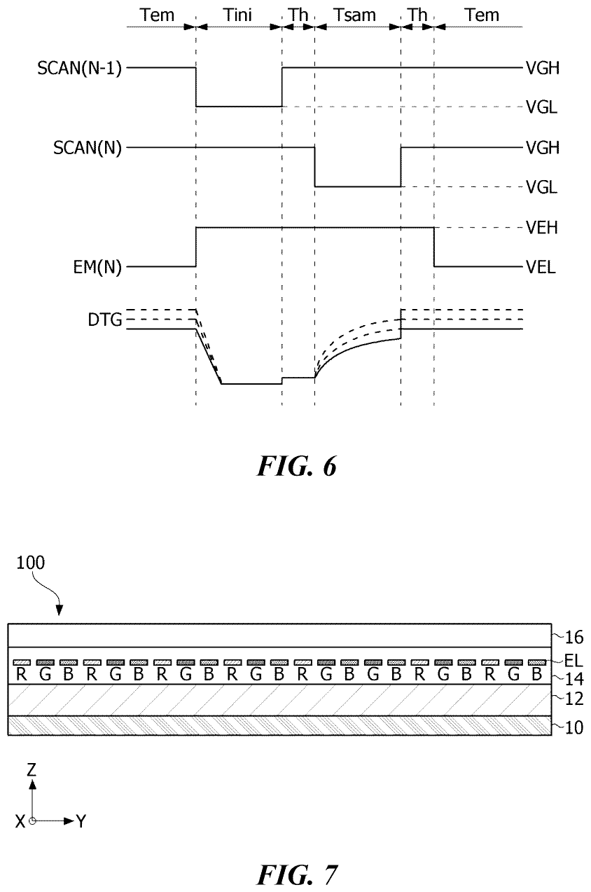

FIGS. 4 and 5 are circuit diagrams illustrating various pixel circuits of a display area of a display apparatus according to an embodiment of the present disclosure. FIG. 6 is a waveform diagram illustrating a driving signal applied to the pixel circuit shown in FIG. 5.

Referring to FIG. 4, the pixel circuit may include a light-emitting element EL, a driving element DT, a switch element M01, and a capacitor Cst, but embodiments of the present disclosure are not limited thereto. In the pixel circuit, the driving element DT and the switch element M01 may be implemented as, but are not limited to, n-channel transistors.

The switch element M01 may connect a data line DL in response to a scan pulse SCAN. For example, the switch element M01 may be turned on in response to a gate-on voltage of the scan pulse SCAN to connect the data line DL to a gate electrode of the driving element DT.

The driving element DT may supply a current to the light-emitting element EL. The driving element DT may include a first electrode, a gate electrode, and a second electrode.

The first electrode may be connected to a VDD line PL to which a pixel driving voltage ELVDD is applied. The gate electrode may be connected to the switch element M01 and the capacitor Cst. The second electrode may be connected to the light-emitting element EL. And the driving element DT drives the light-emitting element EL by supplying a current to the light-emitting element EL according to the gate-source voltage Vgs. Here, the light-emitting element EL may be turned on to emit light when a forward voltage between an anode electrode and a cathode electrode thereof is greater than or equal to a threshold voltage.

The capacitor Cst may be connected to the gate electrode of the driving element DT. The capacitor Cst may be connected between the gate electrode and the second electrode of the driving element DT to store the gate-source voltage Vgs of the driving element DT.

The pixel circuit illustrated in FIG. 5 may further include an EM switch element. The EM switch element may switch a current path of the light-emitting element EL in response to an EM pulse. The EM switch element may be connected between the pixel driving voltage ELVDD and the driving element DT or between the driving element DT and the light-emitting element EL.

Referring to FIGS. 5 and 6, the pixel circuit includes a light-emitting element EL, a driving element DT for supplying a current to the light-emitting element EL, and a switch circuit.

The switch circuit may switch the voltage applied to the light-emitting element EL and the driving element DT. The switch circuit is connected to power lines PL1, PL2, and PL3 to which a pixel driving voltage ELVDD, a low potential voltage ELVSS, and an initialization voltage Vini are applied, a data line DL, and gate lines GL1, GL2, and GL3. The switch circuit may switch the voltage applied to the light-emitting element EL and the driving element DT in response to scan pulses [SCAN(N-1) and SCAN(N)] and the EM pulse [EM(N)].

The switch circuit may sample the threshold voltage Vth of the driving element DT using a plurality of switch elements M1 to M6, store the sampled threshold voltage Vth in the capacitor Cst, and compensate for the gate voltage of the driving element DT by the threshold voltage Vth of the driving element DT. The driving element DT and the switch elements M1 to M6 may be implemented as, but not limited to, p-channel transistors.

The driving period of the pixel circuit may be divided into an initialization period Tini, a sampling period Tsam, and an emission period Tem, as shown in FIG. 6.

An (N)th scan pulse [SCAN(N)] may be generated as the gate-on voltage VGL during the sampling period Tsam and applied to a first gate line GL1. An (N-1)th scan pulse [SCAN(N-1)] may be generated prior to the (N)th scan pulse [SCAN(N)] and applied to a second gate line GL2. The (N-1)th scan pulse [SCAN(N-1)] may include the initialization period Tini. The EM pulse [EM(N)] may be generated as the gate-off voltage VEH during the initialization period Tini and the sampling period Tsam and applied to a third gate line GL3.

During the initialization period Tini, the (N-1)th scan pulse [SCAN(N-1)] may be generated as the gate-on voltage VGL and applied to the second gate line GL2. During the initialization period Tini, the voltages of the first and third gate lines GL1 and GL3 may be the gate-off voltages VGH and VEH, respectively.

The (N)th scan pulse [SCAN(N)] may be generated as a pulse of the gate-on voltage VGL during the sampling period Tsam and applied to the first gate line GL1. During the sampling period Tsam, the voltages of the second and third gate lines GL2 and GL3 are the gate-off voltage VGH.

The EM pulse [EM(N)] may be generated as the gate-on voltage VEL during at least a portion of the emission period Tem and applied to the third gate line GL3. During the emission period Tem, the voltages of the first and second gate lines GL1 and GL2 may be the gate-off voltage VGH.

An anode electrode of the light-emitting element EL may be connected to a fourth node n4 between a fourth and a sixth switch transistors M4 and M6. The fourth node n4 may be connected to the anode electrode of the light-emitting element EL, a second electrode of the fourth switch element M4, and a second electrode of the sixth switch element M6. A cathode electrode of the light emitting element EL may be connected to an ELVSS line PL3 to which the low potential supply voltage ELVSS is applied. The light-emitting element EL may emit by a current flowing according to the gate-source voltage Vgs of the driving element DT. The current path of the light-emitting element EL may be switched by a second and the fourth switch elements M2 and M4.

The capacitor Cst may be connected between an ELVDD line PL1 and a second node n2. The capacitor Cst may include a first electrode connected to the ELVDD line PL1 and a second electrode connected to the second node n2. A data voltage Vdata compensated by the threshold voltage Vth of the driving element DT may be charged to the capacitor Cst. In each of the sub-pixels, the data voltage Vdata is compensated by the threshold voltage Vth of the driving element DT, thereby compensating the characteristic deviation (or difference) of the driving element DT in the sub-pixels.

The first switch element M1 may be turned on according to the gate-on voltage VGL of the (N)th scan pulse [SCAN(N)] to connect the second node n2 and a third node n3. The second node n2 may be connected to the gate electrode of the driving element DT, the second electrode of the capacitor Cst, and a first electrode of the first switch element M1. The third node n3 may be connected to the second electrode of the driving element DT, a second electrode of the first switch element M1, and a first electrode of the fourth switch element M4. A gate electrode of the first switch element M1 may be connected to the first gate line GL1 to receive the (N)th scan pulse [SCAN(N)]. The first electrode of the first switch element M1 may be connected to the second node n2, and the second electrode of the first switch element M1 may be connected to the third node n3.

Since the first switch element M1 is turned on for one horizontal period 1H in which the (N)th scan pulse [SCAN(N)] is generated as the gate-on voltage VGL in one frame period, a leakage current may be generated in its off state. In order to suppress the leakage current of the first switch element M1, the first switch element M1 may be implemented by a transistor with a dual gate structure in which two transistors are connected in series, but embodiments of the present disclosure are not limited thereto.

The second switch element M2 may be turned on according to the gate-on voltage VGL of the (N)th scan pulse [SCAN(N)] to supply the data voltage Vdata to the first node n1. A gate electrode of the second switch element M2 may be connected to the first gate line GL1 to receive the (N)th scan pulse [SCAN(N)]. A first electrode of the second switch element M2 may be connected to the first node n1. A second electrode of the second switch element M2 may be connected to the data line DL to which the data voltage Vdata is applied. The first node n1 may be connected to the first electrode of the second switch element M2, a second electrode of the third switch element M3, and the first electrode of the driving element DT.

The third switch element M3 may be turned on according to the gate-on voltage VGL of the EM pulse [EM(N)] to connect the ELVDD line PL1 to the first node n1. A gate electrode of the third switch element M3 may be connected to the third gate line GL3 to be supplied with the EM pulse [EM(N)]. A first electrode of the third switch element M3 may be connected to the ELVDD line PL1. And the second electrode of the third switch element M3 may be connected to the first node n1.

The fourth switch element M4 may be turned on according to the gate-on voltage VEL of the EM pulse [EM(N)] to connect the third node n3 to the fourth node n4. A gate electrode of the fourth switch element M4 may be connected to the third gate line GL3 to be supplied with the EM pulse [EM(N)]. A first electrode of the fourth switch element M4 may be connected to the third node n3 and a second electrode thereof may be connected to the fourth node n4.

The fifth switch element M5 may be turned on according to the gate-on voltage VGL of the (N-1)th scan pulse [SCAN(N-1)] to connect the second node n2 to the Vini line PL2. A gate electrode of the fifth switch element M5 may be connected to the second gate line GL2 to be supplied with the (N-1)th scan pulse [SCAN(N-1)]. A first electrode of the fifth switch element M5 may be connected to the second node n2, and a second electrode thereof may be connected to the Vini line PL2 to which the initialization voltage Vini is applied. In order to suppress the leakage current of the fifth switch element M5, the fifth switch element M5 may be implemented by a transistor with a structure in which two transistors are connected in series, but embodiments of the present disclosure are not limited thereto.

The sixth switch element M6 may be turned on according to the gate-on voltage VGL of the (N)th scan pulse [SCAN(N)] to connect the Vini line PL2 to the fourth node n4. A gate electrode of the sixth switch element M6 may be connected to the second gate line GL2 to be supplied with the (N)th scan pulse [SCAN(N)]. A first electrode of the sixth switch element M6 may be connected to the Vini line PL2, and a second electrode thereof may be connected to the fourth node n4. In another embodiment, the gate electrodes of the fifth and the sixth switch elements M5 and M6 may be connected in common to the second gate line GL2 to which the (N-1)th scan pulse [SCAN(N-1)] is applied. In this case, the fifth and the sixth switch elements M5 and M6 may be turned on simultaneously in response to the (N-1)th scan pulse [SCAN(N-1)] during the initialization period Tini.

The driving element DT may drive the light-emitting element EL by regulating the current flowing to the light-emitting element EL according to the gate-source voltage Vgs. The driving element DT may include a gate connected to the second node n2, a first electrode connected to the first node n1, and a second electrode connected to the third node n3.

During the initialization period Tini, the (N-1)th scan pulse [SCAN(N-1)] may be generated as the gate-on voltage VGL. The (N)th scan pulse [SCAN(N)] and the EM pulse [EM(N)] may maintain the gate high and the gate off voltages VGH and VEH during the initialization period Tini. Accordingly, during the initialization period Tini, the fifth switch element M5 may be turned on, and thus the second node n2 may be initialized to the initialization voltage Vini. When the fifth and the sixth switch elements M5 and M6 are turned on during the initialization period Tini, the second and fourth nodes n2 and n4 may be initialized to the initialization voltage Vini.

A hold period Th may be set between the initialization period Tini and the sampling period Tsam, and between the sampling period Tsam and the emission period Tem. In the hold period, the scan pulses [SCAN(N-1) and SCAN(N)] and the EM pulse [EM(N)] are at the gate-off voltage VGH, and the major nodes n1 through n4 of the pixel circuit may be floated.

During the sampling period Tsam, the (N)th scan pulse [SCAN(N)] may be generated as the gate-on voltage VGL. The pulse of the (N)th scan pulse [SCAN(N)] may be synchronized to the data voltage Vdata of the pixel data to be written to the sub-pixels of the (N)th pixel line. The (N-1)th scan pulse [SCAN(N-1)] and the EM pulse [EM(N)] may be at the gate-off voltages VGH and VEH, respectively, during the sampling period Tsam. Therefore, the first and second switch elements M1 and M2 may be turned on during the sampling period Tsam. At this time, the sixth switch element M6 may also be turned on to supply the fourth node n4 with the initialization voltage Vini, thus preventing the light-emitting element EL from emitting.

During the sampling period Tsam, the gate voltage DTG of the driving element DT may be raised by the current flowing through the first and second switch elements M1 and M2. In the sampling period Tsam, the threshold voltage Vth of the driving element DT may be sampled in the capacitor Cst.

During the emission period Tem, the EM pulse [EM(N)] may be generated as the gate-on voltage VGL. During the emission period Tem, the voltage of the EM pulse [EM(N)] may be inverted to a predetermined duty ratio. Thus, the EM pulse [EM(N)] may be generated as the gate-on voltage VGL for at least a portion of the emission period Tem.

When the EM pulse [EM(N)] is at the gate-on voltage VEL, a current flows between the pixel driving voltage ELVDD and the light-emitting element EL, causing the light-emitting element EL to emit light. During the emission period Tem, the (N-1) and the (N)th scan pulses [SCAN(N-1) and SCAN(N)] may be at the gate-off voltage VGH. During the emission period Tem, the third and fourth switch elements M3 and M4 may be turned on according to the gate-on voltage VEL of the EM pulse. When the EM pulse [EM(N)] is at the gate-on voltage VEL, the third and fourth switch elements M3 and M4 are turned on, causing a current to flow to the light-emitting element EL. During the emission period Tem, the current flowing through the light-emitting element EL is as follows: K(ELVDD-Vdata)². Herein, K is a constant value that is determined by the charge mobility, parasitic capacitance, and channel capacity of the driving element DT.

According to an embodiment of the present disclosure, as the EM pulse emits light at low luminance, the width of the gate-on voltage VGL may be narrowed and the interval of the gate-high voltages VGH and VEH may increase. Therefore, when the dummy pad is connected to the driving pad that supply the EM pulse, the gate high voltage may be applied to the dummy pads.

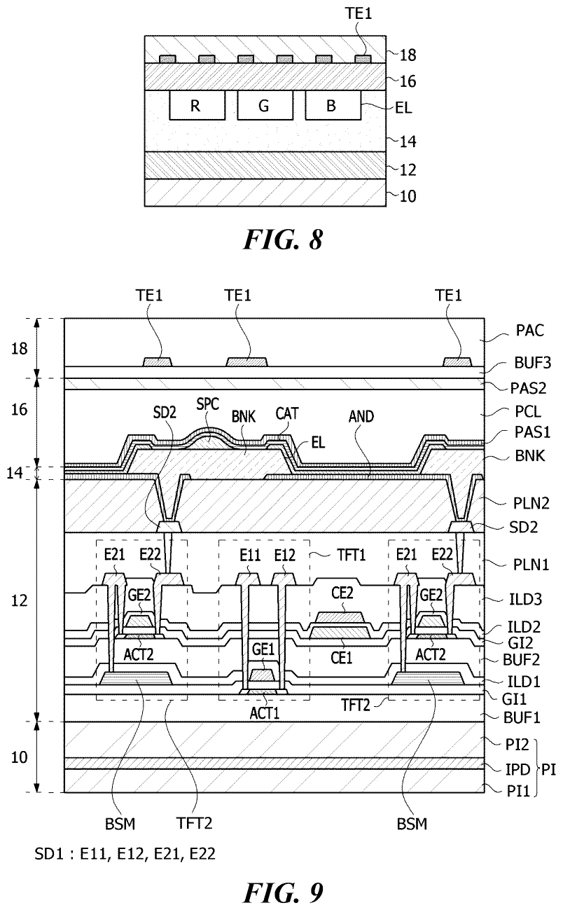

FIG. 7 is a cross-sectional view illustrating a cross-sectional structure of a display area according to an embodiment of the present disclosure. FIG. 8 is a cross-sectional view illustrating a cross-sectional structure of a display area according to another embodiment of the present disclosure. FIG. 9 is a diagram illustrating a cross-sectional structure of a display area according to another embodiment of the present disclosure.

Referring to FIG. 7, the display panel 100 may include a circuit layer 12, an emissive element layer 14, and an encapsulation layer 16 that are stacked on a substrate 10.

The substrate 10 may be formed of an insulating material or a material with flexibility. For example, the substrate 10 may be made of glass, metal, or plastic, but is not limited thereto. When the substrate 10 is made of plate-shaped alkali-free glass or non-alkali glass, it may be more impact resistant and less deformable than a plastic substrate.

The circuit layer 12 may include a pixel circuit connected to the wires such as the data lines, the gate lines, and the power lines, and the gate driver connected to the gate lines. In addition, the wires and the circuit elements in the circuit layer 12 may include a plurality of insulating layers, two or more metal layers separated with an insulating layer therebetween, and an active layer containing a semiconductor material.

The emissive element layer 14 may include a light-emitting element EL driven by the pixel circuit. The light-emitting element EL may include a plurality of red light-emitting elements R, a plurality of green light-emitting elements G, and a plurality of blue light-emitting elements B. In another embodiment, the emissive element layer 14 may further include a white light-emitting element and a color filter. The light-emitting elements EL of the emissive element layer 14 may be covered by the encapsulation layer including an organic film and an inorganic film.

The encapsulation layer 16 may cover the emissive element layer 14 to seal the circuit layer 12 and the emissive element layer 14. The encapsulation layer 16 may have a multi-insulating film structure with alternating organic and inorganic films stacked, but embodiments of the present disclosure are not limited thereto. The inorganic film may block the ingress of moisture and oxygen. The organic film may planarize the surface of the inorganic film. When the organic layer and the inorganic layer are stacked in multiple layers, the movement path of moisture or oxygen introduced from the outside becomes longer compared to the encapsulation composed of a single layer, and thus the ingress of moisture/oxygen affecting the emissive element layer 14 may be effectively blocked.

Referring to FIG. 8, the display panel 100 may further include a touch sensor layer 18 formed on the encapsulation layer 16. The touch sensor layer 18 may be implemented by capacitive touch sensors that sense a touch input based on changes in capacitance before and after the touch input. The touch sensor layer 18 may include sensor electrodes TE1 that form the capacitance of the touch sensors. The capacitance of the touch sensor may be formed between the sensor electrodes TE1. The touch sensor layer 18 may include an organic film covering the sensor electrodes TE1 of the touch sensors.

Referring to FIG. 9, a plurality of pixel circuits and wires connected to the pixel circuits may be disposed in the display area DA of the display panel 100. The pixel circuits of the display area DA may include a pixel circuit of a red sub-pixel driving a red light-emitting element, a pixel circuit of a green sub-pixel driving a green light-emitting element, and a pixel circuit of a blue sub-pixel driving a blue light-emitting element. And a plurality of circuit areas is separated along the X-axis direction of the display panel 100 within the display area DA.

A substrate PI may include a first and second substrate PI1 and PI2. An inorganic film IPD may be formed between the first substrate PI1 and the second substrate PI2. The inorganic film IPD may block the ingress of moisture from the outside.

A first buffer layer BUF1 may be formed on the second substrate PI2. The first buffer layer BUF1 may be formed of a multi-layer insulating film with two or more layers of oxide film (SiO₂) and nitride film (SiNx) stacked. A first semiconductor layer may be formed on the first buffer BUF1. The first semiconductor layer may include a polysilicon semiconductor layer. The first semiconductor layer may include a polysilicon active layer ACT1 that forms a semiconductor channel in the first TFT TFT1.

A first gate insulating layer GI1 may be formed on the first buffer layer BUF1 to cover the active layer ACT1 of the first semiconductor layer. The first gate insulation layer GI1 may include a layer of inorganic insulating material. A first metal layer may be formed on the first gate insulating layer GI1. The first metal layer may be insulated from the first semiconductor layer by a first gate insulating layer GI1.

The first metal layer may include a single-layer metal or a multi-layer metal with two or more metal layers stacked on top of each other. The first metal layer may include a gate electrode GE1 of the first TFT TFT1, and a light shielding layer BSM under a second TFT TFT 2.

A first interlayer insulating layer ILD1 may be formed on the first gate insulating layer GI1. The first interlayer insulating layer ILD1 may cover the first metal layer. The first interlayer insulating layer ILD1 may contain an inorganic insulating material. A second buffer layer BUF2 may be formed on the first interlayer insulating layer ILD1. The second buffer layer BUF2 may include a single or multiple layers of inorganic insulating material, but embodiments of the present disclosure are not limited thereto.

The second semiconductor layer may include an oxide semiconductor layer ACT2 that forms a semiconductor channel in the second TFT TFT2. A second gate insulating layer GI2 may be formed or deposited on the second buffer layer BUF2 to cover an active layer ACT2 of the second semiconductor layer. The second gate insulating layer GI2 may include a single or multiple layers of inorganic insulating material. A second metal layer may be formed on the second gate insulating layer GI2. The second metal layer may be insulated from the second semiconductor layer by the second gate insulating layer GI2.

The second metal layer may include a single layer metal or metals with two or more metal layers stacked on top of the other. The second metal layer may include a gate electrode GE2 of the second TFT TFT2, and a lower capacitor electrode CE1.

A second interlayer insulating layer ILD2 may be formed on the second gate insulating layer GI2. The second interlayer insulating layer ILD2 may cover the second metal layer. The second interlayer insulating layer ILD2 may include a single or multiple layers of inorganic insulating material. A third metal layer may be formed on the second interlayer insulating layer ILD2. The third metal layer may be insulated from the second metal layer by the second interlayer insulating layer ILD2.

The third metal layer may include a single layer metal or a multi-layer metal with two or more metal layers stacked on top of the other. The third metal layer may include an upper capacitor electrode CE2. The capacitor Cst of the pixel circuit may include the upper capacitor electrode CE2, the lower capacitor electrode CE1, and a dielectric layer between the upper capacitor electrode CE2 and the lower capacitor electrode CE1, such as a second interlayer insulating layer ILD2.

A third interlayer insulating layer ILD3 may be formed on the second interlayer insulating layer ILD2. The third interlayer insulating layer ILD3 may cover the third metal layer. The third interlayer insulating layer ILD3 may include a single or multiple layers of inorganic insulating material. A fourth metal layer SD1 may be formed on the third interlayer insulating layer ILD3. The fourth metal layer may be insulated from the second semiconductor layer by the second gate insulating layer GI2.

The fourth metal layer SD1 may contain a single layer metal or a multi-layer metal with two or more metal layers stacked on top of the other. The fourth metal layer SD1 may include the first and the second electrodes E11 and E12 of the first TFT TFT1, and the first and second electrodes E21 and E22 of the second TFT TFT2. The fourth metal layer SD1 may be a first signal wire.

The first and second electrodes E11 and E12 of the first TFT TFT1 may be connected to the first active layer ACT1 through a first contact hole penetrating the insulating layers GI1, ILD1, BUF2, GI2, ILD2, and ILD3. The first and second electrodes E21 and E22 of the second TFT TFT2 may be connected to the second active layer ACT2 through a second contact hole penetrating the insulating layers GI2, ILD2, and ILD3. The first electrode E21 of the second TFT TFT2 may be connected to the light shielding layer BSM through a third contact hole penetrating the insulating layers ILD1, BUF2, GI2, ILD2, and ILD3. The fourth metal layers E11 to E22 may generate fields of high intensity due to voltages swinging between the gate-on voltage and the gate-off voltage with large voltage differences, but embodiments of the present disclosure are not limited thereto.

A first planarization layer PLN1 may cover the fourth metal layers E11 to E22. The first planarization layer PLN1 may be composed of an organic insulating material. The first planarization layer PLN1 may cover the display area DA of the circuit layer 12. When the first planarization layer PLN1 is applied (or formed) on the circuit layer 12, the organic insulating material may flow to the edges of the display panel 100 to cover the side surfaces of the circuit layer 12 in the bezel area BZ.

A fifth metal layer may be formed on the first planarization layer PLN1. The fifth metal layer may be insulated from the fourth metal layer by the first planarization layer PLN1. The fifth metal layer may contain a single layer metal or a multi-layer metal with two or more metal layers stacked on top of each other. The fifth metal layer may include a metal layer SD2 connecting the light-emitting element EL to the second TFT TFT2. The metal layer SD2 may be connected to the second electrode E22 of the second TFT TFT2 through a fourth contact hole penetrating the first planarization layer PLN1.

A second planarization layer PLN2 may be formed on the first planarization layer PLN1 to cover the metal layers of the fifth metal layer. The second planarization layer PLN2 may be composed of an organic insulating material. The second planarization layer PLN2 may cover the display area DA of the circuit layer 12. A sixth metal layer may be formed on the second planarization layer PLN2. The second planarization layer PLN2 may planarize the surface on which the sixth metal layer is formed.

The sixth metal layer may include a single layer metal or a multi-layer with two or more metal layers stacked on top of the other. The sixth metal layer may include an anode electrode AND of the light-emitting element EL. The anode electrode AND may be in contact with the metal layer SD2 connected to the second TFT TFT2 of the pixel circuits through a fifth contact hole penetrating the second planarization layer PLN2.

In the emissive element layer 14, a bank BNK may be formed on the second planarization layer PLN2 to cover the edge of the anode electrode AND. The bank BNK may be formed by a pattern that separates an emission area (or an aperture areas) through which light pass from the respective pixels to the outside. The bank BNK may be patterned during a photolithographic process by including an organic insulating material having photosensitive properties, but embodiments of this specification are not limited thereto.

A spacer SPC having a predetermined height may be formed on the bank BNK. The bank BNK and the spacer SPC may be integrated with the same organic insulating material. The spacer SPC may secure a gap between a fine metal mask (FMM) and the anode electrode AND so that the FMM does not contact the anode electrode AND in the deposition process of the light-emitting element EL formed of an organic compound.

A seventh metal layer used as a cathode electrode CAT of the light-emitting element EL may be formed on the light-emitting element EL implemented by the bank BNK and the organic compound layer. The seventh metal layer may be connected between sub-pixels in the display area DA.

The encapsulation layer 16 may include one or more insulating layers covering the cathode electrode CAT of the light-emitting element EL. The one or more insulating layers may include a first inorganic insulating layer PAS1 covering the cathode electrode CAT, an organic insulating layer PCL covering the first inorganic insulating layer PAS1, and a second inorganic insulating layer PAS2 covering the organic insulating layer PCL.

The touch sensor layer 18 may include a third buffer layer BUF3 covering the second inorganic insulating layer PAS2, a sensor electrode TE1 formed on the third buffer layer BUF3, and an organic insulating layer PAC covering the sensor electrode TE1.

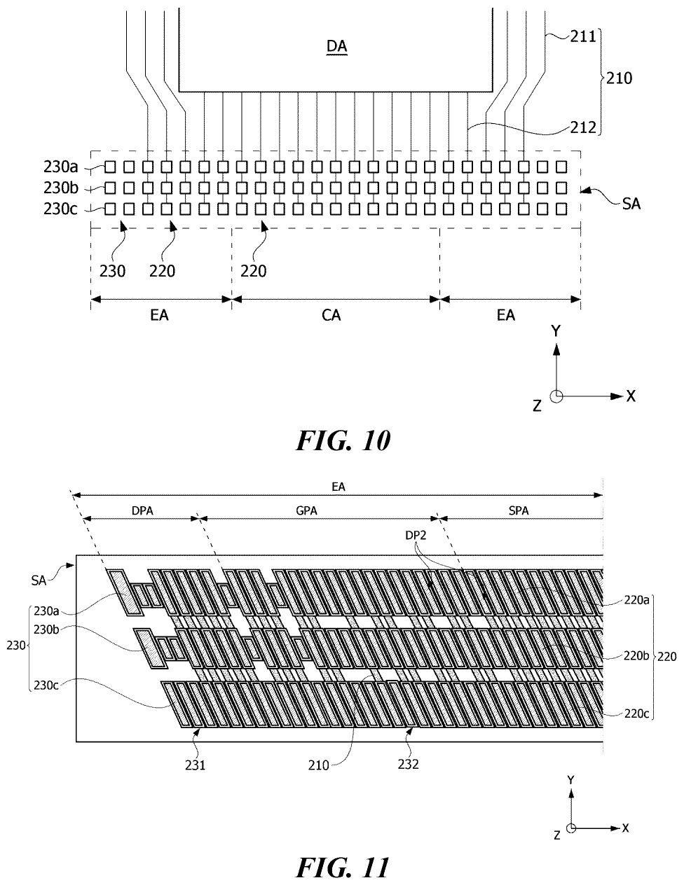

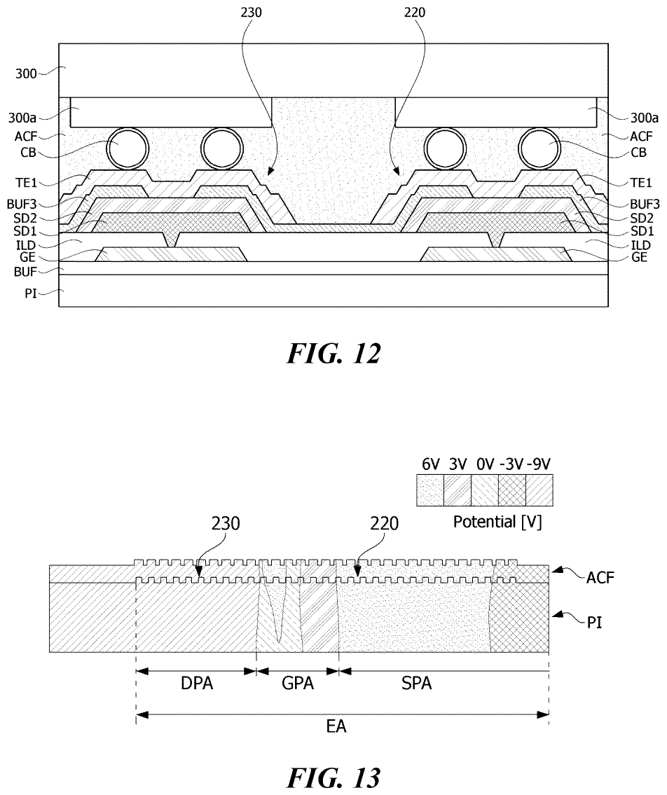

FIG. 10 is a diagram illustrating a signal wire and a pad in a display apparatus according to another embodiment of the present disclosure. FIG. 11 is a diagram illustrating an area EA of FIG. 10. FIG. 12 is a cross-sectional view of a driving pad and a dummy pad according to an embodiment of the present disclosure.

Referring to FIGS. 10 and 11, the first area SA may include an outer side portion EA and a central portion CA. The outer side portion EA may be on one side and on the other side of the first area SA. The outer side portion EA may be on both sides of the central portion CA.

The plurality of signal wires 210 may extend from the display area DA to the first area SA. The plurality of driving pads 220 connected to the signal wires 210 may be disposed in the first area SA.

Some of the plurality of driving pads 220 may be disposed in the central portion CA of the first area SA, and the remainder may be disposed in the outer side portions EA of the first area SA. The dummy pad 230 may be disposed in the outer side portions EA of the first area SA. For example, the remainder of the plurality of driving pads 220 and the dummy pad 230 may be disposed in the outer side portions EA of the first area SA.

Each of the driving pads 220 may be disposed in a direction from the display area DA toward the first area SA. The driving pad 220 may include a plurality of sub-driving pads 220a, 220b, and 220c. The plurality of sub-driving pads 220a, 220b, and 220c may be disposed in the outer side portions EA and the central portion CA of the first area SA. The plurality of sub-driving pads 220a, 220b, and 220c may be disposed in a direction from the display area DA toward the first area SA. The plurality of sub-driving pads 220a, 220b, and 220c may be electrically connected by the signal wire 210. Therefore, even if any one of the sub-driving pads 220a, 220b, and 220c has a contact failure with a bump on the driver IC 300, the signal wire 210 may be connected to the driver IC 300 through the other sub-driving pads 220a, 220b, and 220c.

Each of the driving pads 220 may include, but is not limited to, three sub-driving pads 220a, 220b, and 220c. The number of the plurality of sub-driving pads 220a, 220b, and 220c may be varied depending on the bump structure or design of the driver IC 300.

The dummy pad 230 may be disposed in a direction from the display area DA toward the first area SA. The dummy pad 230 may include a plurality of sub-dummy pads 230a, 230b, and 230c. The plurality of sub-dummy pads 230a, 230b, and 230c may be disposed in a direction from the display area DA toward the first area SA. For example, the plurality of sub-dummy pads 230a, 230b, and 230c and some of the plurality of driving pads 220 and may be disposed on each of the outer side portions EA of the first area SA. The number of the plurality of sub-dummy pads 230a, 230b, and 230c may be varied depending on the bump structure or design specification of the driver IC 300.

Referring to FIG. 11, the outer side portion EA of the first area SA may include a first outer side portion DPA, a second outer side portion GPA, and a third outer side portion SPA.

The first outer side portion DPA may be one side of the first area SA. The plurality of dummy pads 230 may be disposed on the first outer side portion DPA. For example, the plurality of sub-dummy pads 230a, 230b, and 230c may be disposed on the first outer side portion DPA.

The second outer side portion GPA may be disposed adjacent to the first outer side portion DPA. The driving pad 220 connected to the gate wire may be disposed in the second outer side portion GPA.

The third outer side portion SPA may be disposed adjacent to the second outer side portion GPA. The second outer side portion GPA may be between the first outer side portion DPA and the third outer side portion SPA. The driving pad 220 connected to the gate wire may be disposed in the third outer side portion SPA.

The driving pad 220 and the dummy pad 230 may be disposed extending in an oblique direction inclined with respect to a vertical line. The driving pad 220 and the dummy pad 230 may have a parallelogram shape. However, the shape of the driving pad 220 and the dummy pad 230 is not limited to this.

The driving pad 220 may include a plurality of sub-driving pads 220a, 220b, and 220c spaced apart in an oblique direction. The dummy pad 230 may include a plurality of sub-dummy pads 230a, 230b, and 230c spaced apart in an oblique direction. In addition, the signal wire 210 connecting the plurality of sub-driving pads 220a, 220b, and 220c may extend in an oblique direction.

The dummy pad 230 may include a first dummy pad 231 and a second dummy pad 232. The first dummy pad 231 may be disposed on the outer side of the first area SA. The second dummy pad 232 may be disposed between the plurality of driving pads 220. The second dummy pad 232 and the sub-dummy pads 230a, 230b, and 230c may not be connected to each other, but are not necessarily limited thereto.

The first dummy pad 231 may be disposed in plural on the outer side, and thus may be greater in number than the second dummy pad 232. However, the embodiment is not limited thereto, and the number of the second dummy pads 232 may be greater depending on the type of display panel.

The size of the dummy pad 230 may be the same as or larger than that of the driving pad 220. The sizes of the plurality of dummy pads 230 may be the same as each other, but some dummy pads 230 may have different sizes. The plurality of sub-dummy pads 230a, 230b, and 230c may be connected to each other by the signal wire 210, or may be electrically separated from each other.

According to an embodiment of the present disclosure, since the dummy pad 230 is disposed on the outer side or the edge of the first area SA, it may trap the negative charges at the driver IC to prevent electrolytic corrosion in the driving pad 220, and to optimize the area where the driver IC is disposed.

Referring to FIG. 12, the driving pad 220 may include a substrate PI, a buffer layer BUF, a gate electrode GE, a first wire electrode SD1, a second wire electrode SD2, and a sensor electrode TE1.

The buffer layer BUF may be disposed on the substrate PI.

The gate electrode GE may be disposed on the buffer layer BUF. The gate electrode GE may be electrically connected to the signal wire 210. For example, the gate electrode GE may be connected to the signal wire 210 to be electrically connected to the display area.

An interlayer insulating film ILD may disposed on the gate electrode GE. The first wire electrode SD1 may be disposed on the interlayer insulating film ILD. The second wire electrode SD2 may be disposed on the interlayer dielectric film ILD. The second wire electrode SD2 may be disposed on the first wire electrode SD1.

The first wire electrode SD1 may be electrically connected to the gate electrode GE by penetrating the interlayer insulating layer ILD. The second wire electrode SD2 may be disposed on the first wire electrode SD1 and electrically connected to the first wire electrode SD1. However, it is not necessary to be limited thereto, and only any one of the first wire electrode SD1 and the second wire electrode SD2 may be disposed.

The third buffer layer BUF3 may be disposed on the second wire electrode SD2.

A sensor electrode TE1 may be disposed on the third buffer layer BUF3 and

electrically connected to the second wire electrode SD2. The sensor electrode TE1 may be made wide enough to cover the second wire electrode SD2. Therefore, the driving pad 220 and the bump 300a of the driver IC 300 may be stably connected to each other.

An anisotropic conductive film ACF may be disposed between the driving pad 220 and the bump 300a of the driver IC 300. Thus, the driving pad 220 and the bump 300a of the driver IC 300 may be electrically connected by the conductive particles CB.

According to an embodiment of the present disclosure, the driving pad 220 may be configured using the gate electrode GE, the first wire electrode SD1, the second wire electrode SD2, and the sensor electrode TE1 in the display area.

The driving pad 220 may be structurally modified in various ways. As an example, it may be composed of any one or more of the first wire electrode SD1, the second wire electrode SD2, and the sensor electrode TE1 disposed on the gate electrode GE. As an example, the sensor electrode may be omitted and the second wire electrode SD2 may be connected to the bump 300a of the driver IC 300. For example, the driving pad 220 may form structurally different driving pads 220 using a metal layer disposed in the display area.

The dummy pad 230 may have the same structure as the driving pad 220. For example, the dummy pad 230 may differ from the driving pad 220 in that it is not connected to the signal wire 210, and the configuration of the pad itself may be the same. Therefore, since the driving pad 220 and the dummy pad 230 have the same height, the flatness of the driver IC 300 may be maintained to increase driving reliability.

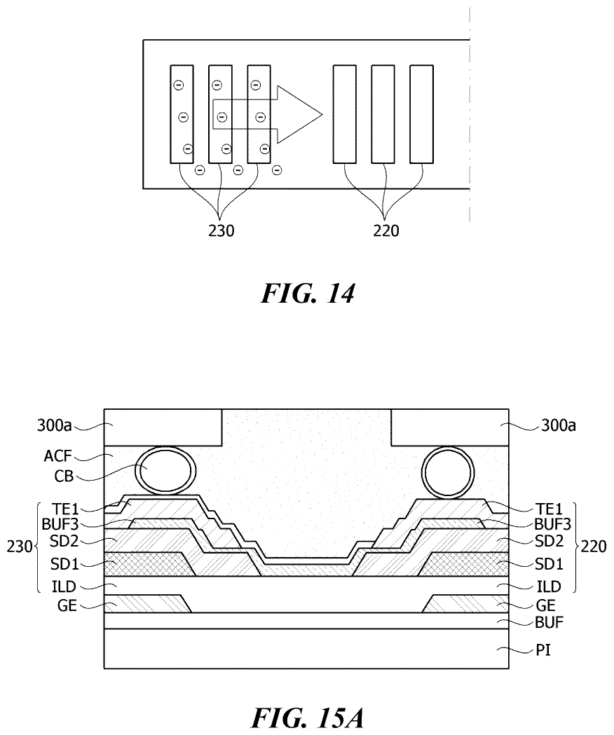

FIG. 13 is a diagram illustrating a potential level of the area EA of FIG. 10. FIG. 14 is a diagram illustrating that the negative charges are concentrated at the edge of the first area in which the driver IC is disposed.

Referring to FIG. 13, the outer side portion EA of the first area SA may include the first outer side portion DPA on which a plurality of dummy pads 230 are disposed, the second outer side portion GPA on which the driving pad 220 connected to the gate wire is disposed, and the third outer side portion SPA on which the driving pad 220 connected to the data wire is disposed. FIG. 13 is a diagram illustrating that the driving pad 220 and the dummy pad 230 are disposed on the substrate PI and the anisotropic conductive film ACF is disposed thereon.

Some of the data wires disposed on the third outer side portion SPA may be supplied with a high level of a positive voltage, while others may be supplied with a relatively low level of a positive or negative voltage. Therefore, some portions of the third outer side portion SPA may have a potential level as high as 6 V, and some other portions thereof may have a potential level as low as −3 V. For example, the initialization voltage or a reset voltage applied to the pixel circuit may be set to a low negative voltage, such as −5 V or −3.3 V.

A clock signal, a scan signal, or an emission control signal may be applied to the driving pad 220 disposed on the second outer side portion GPA, and the clock signal, the scan signal, or the emission control signal may swing between the gate-high voltage and the gate-low voltage.

A negative voltage may be applied to the driving pad 220 disposed closest to the first outer side portion DPA. Therefore, as the driving pad gets closer to the first outer portion DPA, the concentration (or intensity) of negative charges such as OH— increases at the first outer side portion DPA, and thus a low potential level may be formed.

It can be seen that the dummy pad 230 disposed on the first outer side portion DPA is floating, so that the externally introduced negative charges gradually accumulate at the first outer side portion DPA, resulting in the formation a very low potential of −9V. The concentration (or intensity) of the negative charges on the first outer side portion DPA may gradually increase each time a voltage is applied to the driving pad 220.

Referring to FIG. 14, when the display panel is driven, the negative charges concentrated at the edge of the first area SA may be moved (indicated by an arrow) to the driving pad 220 to which a positive voltage is applied, causing electrolytic corrosion to occur in the driving pad 220. As a result, there is a problem of that the electrical connection becomes unstable.

If the negative charges concentrated at the edge of the first area SA are controlled not to move to the driving pad 220 to which the positive voltage is applied, the electrolytic corrosion in the driving pad 220 to which the positive voltage is applied may be inhibited or delayed.

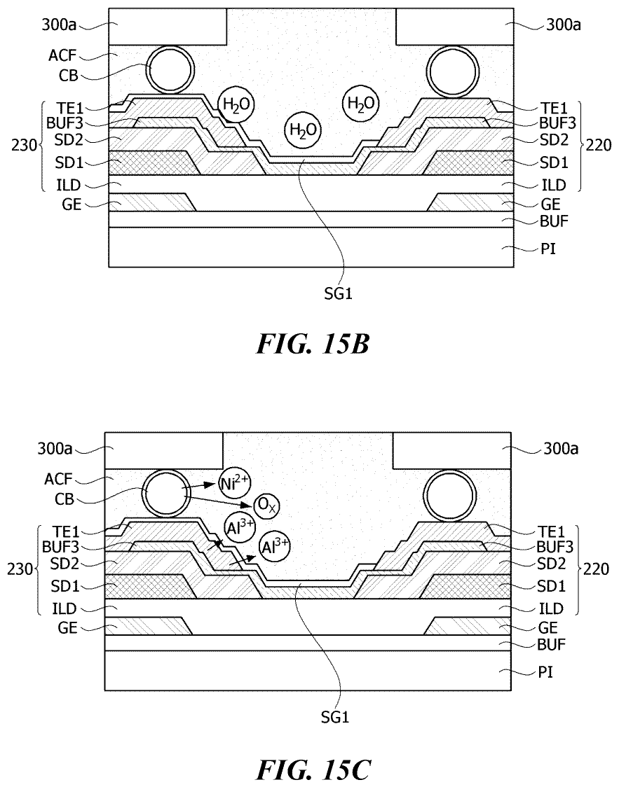

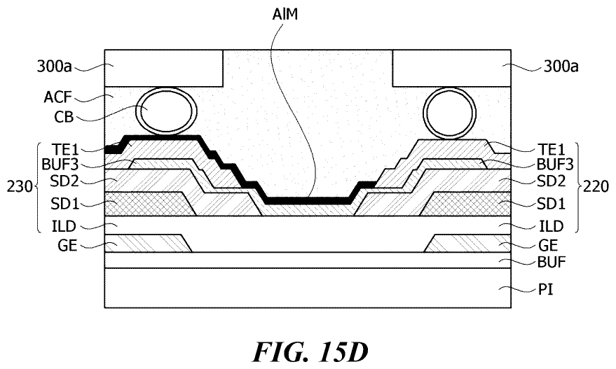

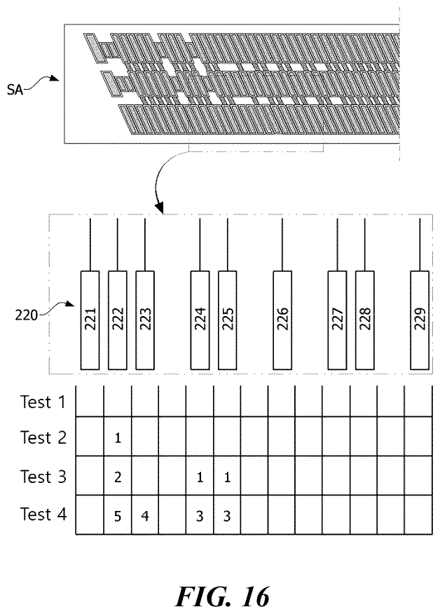

FIGS. 15A to 15D are diagrams illustrating that electrolytic corrosion in the driving pad occurs due to negative charges charged at the edge of the first area. FIG. 16 is a plot where the number of times a defect has occurred in each driving pad is measured.

Referring to FIG. 15A, the anisotropic conductive film ACF may be disposed on the dummy pad 230 and the driving pad 220 to be electrically connected to the bump 300a of the driver IC 300 by conductive particles CB. However, the anisotropic conductive film ACF is susceptible to moisture, which may cause a gap SG1 to form between it and the driving pad 220. Thus, the ingress of external moisture (H₂O) into the gap SG1 may be accelerated, as shown in FIG. 15B.

Referring to FIG. 15C, when a positive voltage is applied while moisture ingress is accelerated, negative charges may be introduced into the driving pad 220, causing electrolytic corrosion to occur. In addition, metallic components of the driving pad 220, such as aluminum ions (Al³⁺), nickel ions (Ni²⁺), and oxygen ions (Ox), may migrate. In this process, a short-circuit wire AIM, which is electrically connected to an adjacent driving pad 220, is formed, as shown in FIG. 15D, resulting in electrical failure.

Referring to FIG. 16, it was observed that among the outermost disposed driving pads 220, a driving pad 220 with a negative voltage applied did not experience any electrolytic corrosion, while a driving pad 220 with a relatively high positive voltage applied experienced a high number of electrolytic corrosion.

As an example, for a second driving pad 222, one defect was detected in the second test, and two and five defects were detected in the third and fourth tests, respectively. The second driving pad 222, a third driving pad 223, a fourth driving pad 224, and a fifth driving pad 225 are all driving pads to which a high voltage is applied. On the other hand, a first driving pad 220, to which a negative voltage is applied, showed no defect in all of the four tests. Therefore, it may be seen that defects have mainly occurred in the driving pad to which a positive voltage is applied.

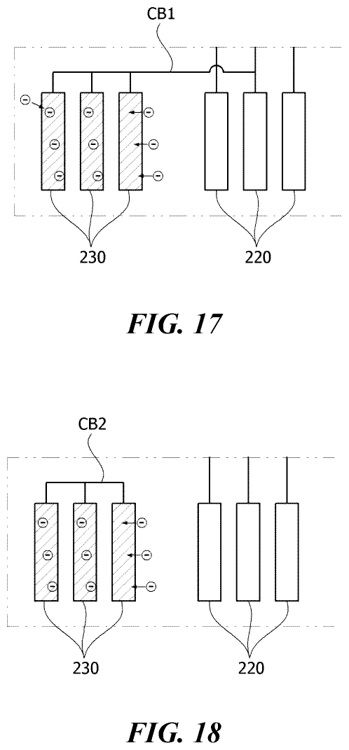

FIGS. 17 to 19 are diagrams illustrating various connection relationships of a dummy pad in a display apparatus according to an embodiment of the present disclosure.

Referring to FIG. 17, when a positive voltage is applied to a plurality of dummy pads 230, they may attract the negative charges concentrated at the edge of the first area SA. Thus, the negative charges do not move to the driving pad 220 to which a positive voltage is applied, thereby inhibiting or preventing electrolytic corrosion in the driving pad 220.

The plurality of dummy pads 230 may be connected in parallel with each other to form an equipotential. At least one of the plurality of dummy pads 230 may be electrically connected to the driving pad 220 to which a positive voltage is applied by the connecting wire CB1. Thus, when the positive voltage is applied to the driving pad 220, the same level of the positive voltage may be applied to the plurality of dummy pads 230.

According to an embodiment of the present disclosure, the dummy pads 230, to which a positive voltage having a high voltage level is applied, may be connected to the driving pad 220 to strongly restrict the negative charges. Therefore, the voltage applied to the plurality of dummy pads 230 may be equal to the highest of the positive voltages applied to the plurality of driving pads 220.

However, it is not necessarily limited to this, and the voltage applied to the plurality of dummy pads 230 may be lower than the highest of the positive voltages applied to the plurality of driving pads 220. In a case where the dummy pad 230 is difficult to be connected to the driving pad 220 to which a high level of positive voltage is applied because it is separated from that driving pod 220, the dummy pad 230 may be connected to another driving pad 220, to which the highest voltage is applied, among the driving pads 220 that may be disposed in close proximity to and capable of being connected to the dummy pad 230.

Referring to FIG. 18, the voltage to be applied to the dummy pad 230 may be applied directly through the driver IC 300. For example, the dummy pad 230 and the driving pad 220 may be electrically isolated and a voltage to the dummy pad 230 may be provided by the driver IC 300 or a power management integrated circuit (PMIC). The plurality of dummy pads 230 may be connected in parallel by a connecting wire CB2 to form an equipotential.

In this way, the positive voltage applied to the dummy pad 230 may be set higher than the voltage applied to the driving pad 220, thereby increasing the restrictive force on the negative charges. In addition, the positive voltage may be applied to the dummy pad 230 at a timing different from the timing of the driving of the driving pad 220. Accordingly, it is possible to prevent the negative charges from moving by periodically applying a positive voltage to the dummy pad 230 even when the display apparatus is turned off.

However, it is not necessarily limited thereto, and some of the dummy pads 230 may be electrically connected to the driving pad 220, and some of them may be supplied with a positive voltage directly through the driver IC 300.

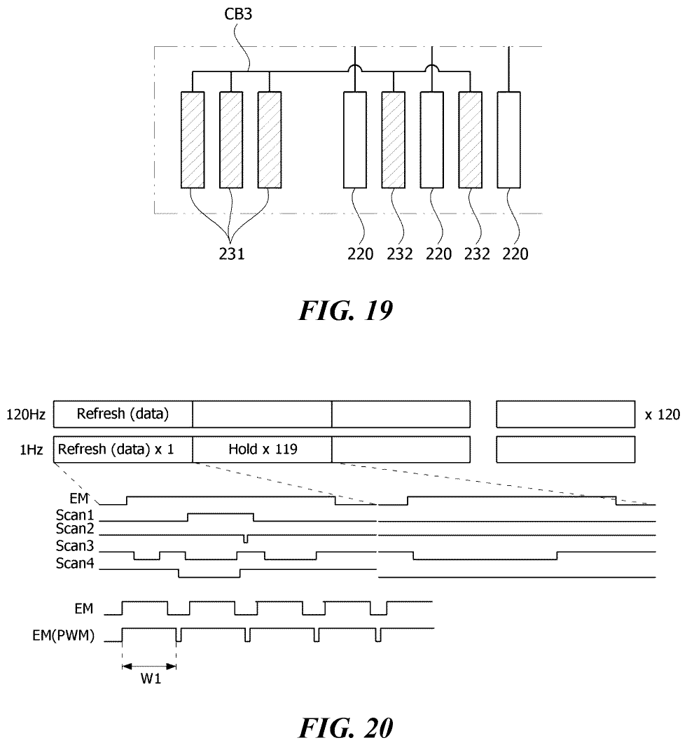

Referring to FIG. 19, a plurality of dummy pads 230 may include a first dummy pad 231 disposed at an edge of the first area SA and a second dummy pad 232 disposed between the plurality of driving pads 220. A plurality of first dummy pads 231 and second dummy pads 232 may be connected by a connecting wire CB3 to form an equipotential.

In this way, it is possible to prevent the negative charges concentrated at the edge of the first area SA, as well as the negative charges at the periphery of the driving pad 220 to which a positive voltage is applied, from reacting with the driving pad 220.

A positive voltage applied to the first dummy pad 231 and a positive voltage applied to the second dummy pad 232 may have different voltage levels. For example, the first dummy pad 231 may be coupled to the driving pad 220 to which a clock voltage of 2 V is applied. For example, the second dummy pad 232 may be coupled to the driving pad 220 to which a gate-high voltage of 6 V is applied.

In another example, a positive voltage may be directly applied to the first dummy pad 231 from the driver IC, and the second dummy pad 232 may be connected to a surrounding driving pad 220. In this case, the first dummy pad 231 receives a high positive voltage, which may strongly restrict the negative charges concentrated at the edge of the first area, while the second dummy pad 232 may have the same voltage as the surrounding driving pad 220, which may minimize parasitic capacitance.

FIG. 20 is a diagram illustrating an operation timing of a pixel circuit in a display apparatus according to an embodiment of the present disclosure.

Referring to FIG. 20, a gate driving signal SCAN2 may be applied as a gate-high voltage in a hold interval after a refresh interval. Thus, in a case where a dummy pad 230 is connected to a driving pad 220 to which the gate-high voltage is applied, a positive voltage may be applied to the dummy pad 230 in the hold interval. For example, a positive voltage may be applied to a dummy pad 230 in the periphery of a driving pad 220 to which the driving signal SCAN2 of the gate-high voltage is applied in the hold interval. When driving at a low-speed of 1 Hz, the hold interval may be 119 times longer than the refresh interval. Thus, a high voltage may be applied to the dummy pad 230 for a relatively long period of time.

In addition, when a light-emitting transistor is a p-channel transistor and is driven by pulse width modulation (PWM), the width of the gate-low voltage VGL of an emission signal EM may become smaller and the width W1 of the gate-high voltage VGH may become larger when driven at low luminance. Thus, when the dummy pad 230 is connected to the driving pad 220 that applies an emission control signal, a high voltage may be applied to the dummy pad 230 when driven at low luminance.

However, it is not necessarily limited thereto, and in a case where the dummy pad 230 is independently powered by the driver IC 300 or the power management integrated circuit (PMIC), a positive voltage may be applied to the dummy pad 230 in synchronization with a signal input derived from the first frame by the driver IC 300 or the power management integrated circuit (PMIC). Alternatively, a positive voltage may be applied to the dummy pad 230 by periodically operating the driver IC 300 or the PMIC in a wake-up mode even when the display apparatus is turned off.

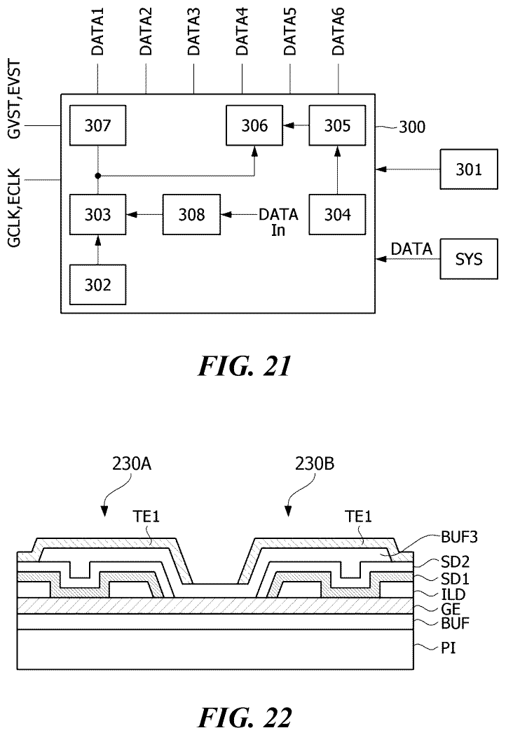

FIG. 21 is a block diagram of the driver IC according to an embodiment of the present disclosure.

Referring to FIG. 21, the driver IC 300 may be coupled to a host system SYS, a first memory 301, and a display panel. The driver IC 300 may include a data receiving and computing part 308, a timing controller 303, a data driver 306, a gamma compensation voltage generator 305, a power supply 304, a second memory 302, and the like, but embodiments of the present disclosure are not limited thereto.

The data receiving and computing part 308 may include a receiving part and a data computing part. The receiving part may receive pixel data input as a digital signal from the host system SYS. The data computing part may process the pixel data input through the receiving part to improve image quality.

The data computing part may include a data restoration part and an optical compensation part. The data restoration part may decode and restore the pixel data in a compressed state. The optical compensation part may add a preset optical compensation value to the pixel data. The optical compensation value may be set as a value for correcting the luminance of each pixel data based on the luminance of the screen of the display panel that has measured based on camera images taken during the manufacturing process.

The timing controller 303 may provide the pixel data of the input image received from the host system SYS to the data driver 306. The timing controller 303 may generate a gate timing signal for controlling the gate driver and a source timing signal for controlling the data driver 306 to control the operation timings of the gate driver and the data driver 306.

The data driver 306 may convert digital data, including the pixel data, received from the timing controller 303 to a gamma compensation voltage using a digital to analog converter (DAC) and output a data voltage. Data voltages DATA1 to DATA6 output from the data driver 306 may be supplied to the data lines of the pixel array through output buffers connected to data channels in the driver IC 300.

A gamma compensation voltage generator 305 may generate a gamma compensation voltage for each grayscale by dividing a gamma reference voltage from the power supply 304 by means of a voltage division circuit. The gamma compensation voltage may be an analog voltage that is set for each grayscale of the pixel data. The gamma compensation voltage output from the gamma compensation voltage generator 305 may be provided to the data drive 306.

The power supply 304 may generate the power required to drive the pixel array, the gate driver, and the driver IC 300 of the display panel using a direct-current to direct-current (DC-DC) converter. The DC-DC converter may include, but is not limited to, a charge pump, a regulator, a buck converter, a boost converter, and the like.

The power supply 304 may generate DC powers such as the gamma reference voltage, the gate-off voltage VGL, the gate-on voltage VGH, the pixel driving voltage VDD, the low potential power supply voltage VSS, and the initialization voltage Vini by regulating a DC input voltage from the host system SYS. The power supply 304 may also generate a positive voltage to be applied to the dummy pad.

The positive voltage applied to the dummy pad may be equal to or greater than the highest of the voltages applied to the driving pads. The power supply 304 may be disposed within the driver IC 300, or may be provided separately. The power supply 304 may include the power management integrated circuit (PMIC).

The gamma reference voltage may be supplied to the data driver 305. The gate-off voltage VGL and the gate-on voltage VGH may be supplied to the level shifter 307. The level shifter 307 may output clock signals GCLK and ECLK and start signals GVST and EVST. The pixel power, such as the pixel driving voltage VDD, the low potential power voltage VSS, and the initialization voltage Vini, may be commonly supplied to the pixels P.

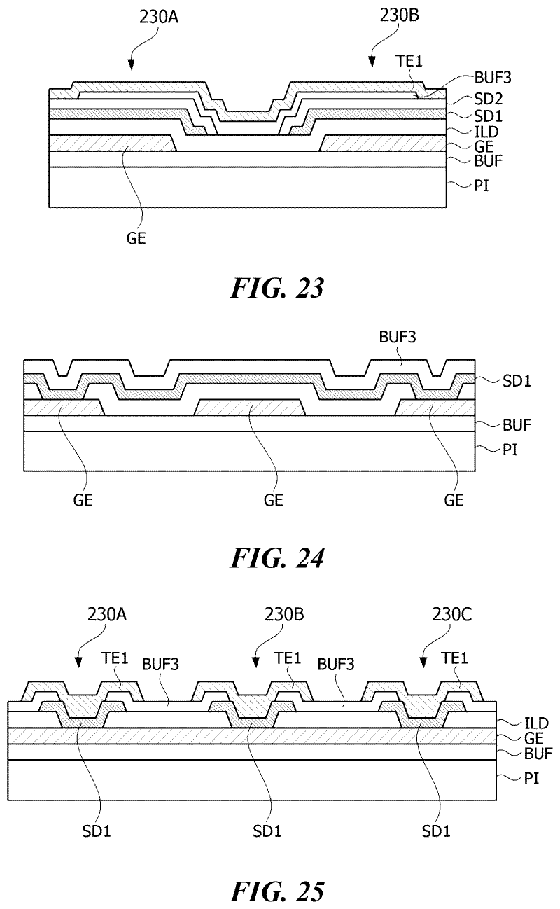

FIG. 22 is a diagram illustrating that a plurality of dummy pads electrically is connected using a gate wire in a display apparatus according to an embodiment of the present disclosure. FIG. 23 is a diagram illustrating that a dummy pad is electrically connected using a sensor electrode wire in a display apparatus according to an embodiment of the present disclosure. FIG. 24 is a diagram illustrating that adjacent dummy pads are electrically connected using a data wire in a display apparatus according to an embodiment of the present disclosure. FIG. 25 is a diagram illustrating that negative charges are immobilized by connecting a gate electrode in a display apparatus according to an embodiment of the present disclosure.

Referring to FIG. 22, in a third dummy pad 230A and a fourth dummy pad 230B which are adjacent to each other, the buffer layer BUF and the gate electrode GE may be disposed on the substrate PI, and the first wire electrode SD1 and the second wire electrode SD2 may be disposed on the interlayer insulating layer ILD. Further, the third buffer layer BUF may be disposed on the second wire electrode SD2, and the sensor electrode TE1 may be disposed on the third buffer layer BUF.

The gate electrode GE of the third dummy pad 230A and the gate electrode GE of the fourth dummy pad 230B may be electrically connected. Thus, the first wire electrode SD1 of the third dummy pad 230A is connected to the gate electrode GE, and the first wire electrode SD1 of the fourth dummy pad 230B is connected to the second gate electrode GE, so that the third dummy pad 230A and the fourth dummy pad 230B may be electrically connected.

Referring to FIG. 23, the sensor electrode TE1 of the third dummy pad 230A and the sensor electrode TE1 of the fourth dummy pad 230B may be connected. For example, the sensor electrode TE1 of the third dummy pad 230A and the sensor electrode TE1 of the fourth dummy pad 230B may be directly connected. Accordingly, the area of the dummy pad 230 may be larger than the area of the driving pad 220.

Referring to FIG. 24, a jumping wire may be formed using a first wiring electrode SD1. Therefore, in a case where there is a gate electrode GE connected to a signal wire between the dummy pads, the jumping wire may jump over the gate electrode and connect other adjacent gate electrodes GE.

Referring to FIG. 25, the gate electrode GE or the light shielding layer (BSM of FIG. 9) may be disposed over the substrate PI and the first wire electrode SD1 of the plurality of dummy pads 230A, 230B, and 230C on the light shielding layer may be connected to the gate electrode GE. In this way, all of the plurality of dummy pads 230 may be formed to be an equipotential and a positive voltage is applied to the gate electrode GE, which has the effect of restricting the movement of negative charges over a wide range.

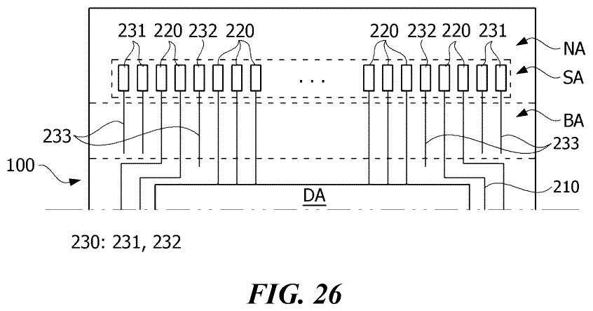

FIG. 26 is a diagram illustrating a display device according to another embodiment of the present disclosure.

Referring to FIG. 26, the display apparatus according to another embodiment of the present disclosure may include a display panel 100, a plurality of signal wires 210, a plurality of driving pads 220, and a dummy pad 230.

The display panel 100 may include a display area DA and a non-display area NA. The non-display area NA may be in the periphery of the display area DA.

The plurality of signal wires 210 may be disposed to extend from the display area DA to the non-display area NA. The plurality of driving pads 220 may be disposed at an end (or a one side) of a plurality of signal wires 210. The plurality of driving pads 220 may be connected to the driver IC.

The dummy pad 230 may be disposed adjacent to the plurality of driving pads 220. The dummy pad 230 may further include a dummy signal wire 233 extending toward the display area DA. Negative charges may be concentrated in the outermost area of the non-display area NA between the first area SA and the display area DA. Thus, the negative charges may be coupled to the signal wire 210 to which a positive voltage is applied, resulting in electrolytic corrosion. The non-display area NA between the first area SA and the display area DA may be the bending area BA. The bending area BA may be between the first area SA and the display area DA. The bending area BA may be subject to accelerated electrolytic corrosion of the signal wire 210 due to stress during the bending.

According to an embodiment of the present disclosure, a high voltage may be applied to the dummy signal wire 233 extending from the dummy pad 230 to inhibit the movement of the negative charges concentrated on the outer side of the driver IC. Therefore, it is possible to solve a problem in which the electrolytic corrosion occurs by coupling the negative charges on the signal wire 210 to which a positive voltage is applied.

The dummy pad 230 may include a first dummy pad 231 and a second dummy pad 232. The first dummy pad 231 may be disposed on the outer side of the signal wire 210. The second dummy pad 232 may be disposed between the plurality of signal wires 210. The same voltage or different voltages may be applied to the first dummy pad 231 and the second dummy pad 232, or different voltages may be applied. Thus, the same voltage or different voltages may be applied to the dummy signal wire 233 connected to the first dummy pad 231 and the dummy signal wire 233 connected to the second dummy pad 232.

The display panel according to embodiments of the present disclosure and the display apparatus including the same may be described as follows.

A display panel according to an embodiment of the present disclosure, may include: a substrate having a display area and a non-display area in the periphery of the display area, a plurality of signal wires extending from the display area to the non-display area, a plurality of driving pads that is disposed in a first area to which a driver IC is attached in the non-display area and that is connected to the plurality of signal wires, and a dummy pad disposed in the first area. A positive voltage may be applied to the dummy pad.

According to one or more embodiments of the present disclosure, the plurality of driving pads may be disposed in the central portion of the first area, and the dummy pad may be disposed at both edges of the first area.

According to one or more embodiments of the present disclosure, the dummy pad may include a first dummy pad disposed at the edges of the first area and a second dummy pad disposed between the plurality of driving pads.

According to one or more embodiments of the present disclosure, the number of first dummy pads may be greater than the number of second dummy pads.

According to one or more embodiments of the present disclosure, the positive voltage applied to the dummy pad may be a voltage equal to the highest of the positive voltages applied to the plurality of driving pads.

According to one or more embodiments of the present disclosure, the positive voltage applied to the dummy pad may be a voltage higher than the highest of the positive voltages applied to the plurality of driving pads.

According to one or more embodiments of the present disclosure, the dummy pad may further include a plurality of sub-dummy pads spaced apart from each other in a direction from the display area toward the first area.

According to one or more embodiments of the present disclosure, the plurality of sub-dummy pads may be electrically connected to each other.

According to one or more embodiments of the present disclosure, the plurality of sub-dummy pads may be electrically isolated from each other.

According to one or more embodiments of the present disclosure, each of the plurality of driving pads may further include a plurality of sub-driving pads spaced apart from each other in a direction from the display area toward the first area. The plurality of sub-driving pads may be electrically connected by the signal wire.

According to one or more embodiments of the present disclosure, the plurality of driving pads and the dummy pad may have the same structure.

According to one or more embodiments of the present disclosure, the plurality of driving pads and the dummy pad may each include a gate electrode disposed on a substrate, a first wire electrode disposed on the gate electrode, a second wire electrode disposed on the first wire electrode, and a sensing electrode disposed on the second wire electrode.

According to one or more embodiments of the present disclosure, the dummy pad may be configured in plural. At least some of the plurality of dummy pads may be connected to any one of the gate electrode, the first wire electrode, the second wire electrode, and the sensing electrode.

According to one or more embodiments of the present disclosure, the gate electrode of the first dummy pad and the gate electrode of the second dummy pad may be electrically connected.

According to one or more embodiments of the present disclosure, the level of the voltages applied to the first dummy pad and the second dummy pad may be different.

According to one or more embodiments of the present disclosure, the level of the voltage applied to the first dummy pad may be higher than the level of the voltage applied to the second dummy pad.

A display apparatus according to one or more embodiments of the present disclosure may include: a substrate having a display area and a non-display area in the periphery of the display area, a plurality of signal wires extending from the display area to the non-display area, a plurality of driving pads disposed in a first area of the non-display area and connected to the plurality of signal wires, a plurality of dummy pads disposed in the first area, and a driver IC disposed in the first area. The plurality of dummy pads may include a plurality of dummy signal wires extending toward the display area.

According to one or more embodiments of the present disclosure, the driver IC may include a plurality of bumps electrically connected to the plurality of driving pads and the plurality of dummy pads.

According to one or more embodiments of the present disclosure, the driver IC may be implemented to apply a positive voltage to the plurality of dummy pads through the plurality of bumps.

According to one or more embodiments of the present disclosure, the positive voltage may be applied to the plurality of dummy pads even during off periods of the display apparatus.

The display apparatus according to an embodiment of the present disclosure may be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation device, an in-vehicle navigation device, an in-vehicle display apparatus, an in-vehicle device, theater device, theater display apparatus, a television, a wallpaper device, a signage device, a gaming device, a laptop, a monitor, a camera, a camcorder, and a home appliance.

The present disclosure described above is not limited to the foregoing embodiments and the accompanying drawings, and it will be apparent to a person skilled in the art to which the present disclosure belongs that various substitutions, modifications, and changes may be made within the scope without departing from the technical spirit of the present disclosure. Therefore, the scope of the present disclosure is represented by the following claims, and it should be construed that all changes or modifications derived from the meaning and scope of the claims and the equivalent concept thereof are included within the scope of the present disclosure.

### DESCRIPTION OF REFERENCE NUMERALS

100: Display panel
210: Signal wire
211: Data wire
212: Gate wire
220: Driving pad
230: Dummy pad
300: Driving IC

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a substrate having a display area and a non-display area adjacent to the display area;
a plurality of signal wires extending from the display area to the non-display area;
a plurality of driving pads disposed in a first area in which a driver IC is disposed in the non-display area and electrically connected to the plurality of signal wires; and
a dummy pad disposed in the first area,
wherein a positive voltage is applied to the dummy pad.

2. The display panel of claim 1, wherein the plurality of driving pads is disposed in a central portion of the first area, and
wherein the dummy pads are disposed at both edges of the first area.

3. The display panel of claim 1, wherein the dummy pad includes:
a first dummy pad disposed at the edges of the first area; and
a second dummy pad disposed between the plurality of driving pads.

4. The display panel of claim 3, wherein the number of first dummy pads is greater than the number of second dummy pads.

5. The display panel of claim 1, wherein the positive voltage applied to the dummy pad is a voltage equal to the highest of the positive voltages applied to the plurality of driving pads.

6. The display panel of claim 1, wherein the positive voltage applied to the dummy pad is a voltage higher than the highest of the positive voltages applied to the plurality of driving pads.

7. The display panel of claim 1, wherein the dummy pad further includes a plurality of sub-dummy pads spaced apart from each other in a direction from the display area toward the first area.

8. The display panel of claim 7, wherein the plurality of sub-dummy pads is electrically connected to each other.

9. The display panel of claim 7, wherein the plurality of sub-dummy pads is electrically isolated from each other.

10. The display panel of claim 1, wherein each of the plurality of driving pads further includes a plurality of sub-driving pads spaced apart from each other in a direction from the display area toward the first area, and
wherein the plurality of sub-driving pads is electrically connected by the signal wire.

11. The display panel of claim 1, wherein the plurality of driving pads and the dummy pad have the same structure.

12. The display panel of claim 11, wherein the plurality of driving pads and the dummy pad each include:
a gate electrode on the substrate;
a first wire electrode on the gate electrode;
a second wire electrode on the first wire electrode; and
a sensing electrode on the second wire electrode.

13. The display panel of claim 12, wherein the dummy pad is configured in plural, and
wherein at least some of the plurality of dummy pads are connected to any one of the gate electrode, the first wire electrode, the second wire electrode, and the sensing electrode.

14. The display panel of claim 3, wherein the gate electrode of the first dummy pad and the gate electrode of the second dummy pad are electrically connected.

15. The display panel of claim 3, wherein the level of the voltages applied to the first dummy pad and the second dummy pad is different.

16. The display panel of claim 3, wherein the level of the voltage applied to the first dummy pad is higher than the level of the voltage applied to the second dummy pad.

17. A display apparatus comprising:
a substrate having a display area and a non-display area adjacent to the display area;
a plurality of signal wires extending from the display area to the non-display area;
a plurality of driving pads disposed in a first area of the non-display area and electrically connected to the plurality of signal wires;
a plurality of dummy pads disposed in the first area; and
a driver IC disposed in the first area,
wherein the plurality of dummy pads includes a plurality of dummy signal wires extending toward the display area.

18. The display apparatus of claim 17, wherein the driver IC includes a plurality of bumps electrically connected to the plurality of driving pads and the plurality of dummy pads.

19. The display apparatus of claim 18, wherein the driver IC is configured to apply a positive voltage to the plurality of dummy pads through the plurality of bumps.

20. The display apparatus of claim 17, wherein the positive voltage is applied to the plurality of dummy pads even during off periods of the display apparatus.
